(19) United States
(12) Patent Application Publication
(10) Pub. No.: US 2012/0168858 A1
(43) Pub. Date: Jul. 5, 2012

(54) NON-VOLATILE MEMORY DEVICE AND METHOD OF FABRICATING THE SAME

(75) Inventor: Young-Ok HONG, Icheon-si (KR)

(73) Assignee: Hynix Semiconductor Inc., Icheon-si (KR)

(21) Appl. No.: 13/243,272

(22) Filed: Sep. 23, 2011

(30) Foreign Application Priority Data
Dec. 30, 2010 (KR) 10-2010-0138820

(51) Int. Cl. H01L 29/78; H01L 21/762

(52) U.S. Cl. 257/330; 438/424; 257/E29.255; 257/E21.546

(57) ABSTRACT

A method of fabricating a non-volatile memory device includes providing a substrate with a cell region where a plurality of memory cells that are stacked vertically are to be formed and a peripheral circuit region where a peripheral circuit device is to be formed. Forming a gate structure where an inter-layer dielectric layer and a gate electrode layer are alternately stacked over the substrate of the cell region and the peripheral circuit region. Forming a first trench that isolates the gate electrode layers in one direction by selectively etching the gate structure of the cell region and forming a trench by selectively etching the gate structure corresponding to a contact formation region of the peripheral circuit region.

### CROSS-REFERENCE TO RELATED APPLICATIONS

The present application claims priority of Korean Patent Application No. 10-2010-0138820, filed on Dec. 30, 2010, which is incorporated herein by reference in its entirety.

### BACKGROUND OF THE INVENTION

Exemplary embodiments of the present invention relate generally to a non-volatile memory device, and a method of fabricating the same, and more particularly, to a non-volatile memory device including a plurality of memory cells stacked perpendicularly to a substrate, and a method of fabricating the same.

Non-volatile memory devices such as flash memories that retain stored data even without power are widely in use.

Fabricating memory devices in a two-dimensional structure where the memory cells are laid in a single layer over a silicon substrate has met certain technical limitations in further improving the degree of high integration. As a measure to overcome this shortfall, there were developments related to non-volatile memory devices of three-dimensional design where the memory cells are stacked over a silicon substrate.

FIG. 1A is a cross-sectional view illustrating a conventional non-volatile memory device having a three-dimensional structure, and FIG. 1B illustrates the dishing effect in a three-dimensional non-volatile memory device shown in FIG. 1A.

Referring to FIG. 1A, shown sequentially disposed over a substrate 100 of a cell region are a pipe gate electrode layer 110 for forming a pipe transistor, a cell gate structure (CGS) where a first inter-layer dielectric layer 135 and a first gate electrode layer 140 are alternately stacked to form a plurality of layers of memory cells, and a selection gate structure (SGS) where a second inter-layer dielectric layer 155, a second gate electrode layer 160, and a second inter-layer dielectric layer 155 are sequentially stacked to form a selection transistor.

A pair of cell channel holes penetrating the cell gate structure (CGS) is disposed inside the cell gate structure (CGS). A pipe channel hole for connecting the pair of cell channel holes to each other is disposed in the inside of the pipe gate electrode layer 110. A pair of selection transistor channel holes penetrating the selection gate structure (SGS) and connected to the pair of cell channel holes respectively is disposed in the inside of the selection gate structure (SGS). A memory gate insulation layer 165 and a channel layer 170 are disposed on the internal walls of the pair of selection transistor channel holes.

As a result, a pipe transistor, a plurality of layers of memory cells, and a selection transistor are disposed over the substrate 100 of the cell region. The pipe transistor is formed of the pipe gate electrode layer 110, the memory gate insulation layer 165 and the channel layer 170 on the internal walls of the pipe channel hole. The plurality of layers of memory cells are formed of the memory gate insulation layer 165 and the channel layer 170 on the internal walls of the pair of cell channel holes and the first gate electrode layer 140 stacked along with the memory gate insulation layer 165 and the channel layer 170 vertically and are isolated for each cell channel hole. The selection transistor is formed of the memory gate insulation layer 165 and the channel layer 170 on the internal walls of the pair of selection transistor channel holes and the second gate electrode layer 160, and isolated for each selection transistor channel hole.

Typical peripheral circuit devices such as a peripheral circuit transistor 120, a capping insulation layer 125, and an inter-layer dielectric layer 130, are disposed in a peripheral circuit region.

However, as the number of stacked memory cells increases in a structure where memory cells are vertically stacked in a cell region as described above, the step height between the cell region and a peripheral circuit region becomes greater, and this makes it difficult to perform subsequent processes. This is illustrated in FIG. 1B.

Referring to FIG. 1B, an inter-layer dielectric layer 180 is disposed over the substrate structure of FIG. 1A.

FIG. 1B illustrates “dishing effect” where the inter-layer dielectric layer 180 sinks in the peripheral circuit region from the boundary between the cell region and the peripheral circuit region due to the step height between the cell region and the peripheral circuit region.

The dishing effect makes it difficult to perform subsequent processes such as forming contacts penetrating the inter-layer dielectric layer 180 and forming lines coupled with the contacts in the upper portion of the inter-layer dielectric layer 180. Since the thickness of the inter-layer dielectric layer 180 is different in the cell region and the peripheral circuit region, it is difficult to control an etch target for forming uniform contacts. Also, since the inter-layer dielectric layer 180 is curved in some regions, the line formed over the curved region may have an abnormal shape.

### SUMMARY OF THE INVENTION

An embodiment of the present invention is directed to a non-volatile memory device that may have a decreased step height between a cell region and a peripheral circuit region and a method for fabricating the same.

A method of fabricating a non-volatile memory device in accordance with an embodiment of the present invention includes: forming a gate structure where an inter-layer dielectric layer and a gate electrode layer are alternately stacked in a cell region and a peripheral circuit region; forming a first trench to isolate the gate electrode layers in one direction by selectively etching the gate structure of the cell region and forming a second trench by selectively etching the gate structure corresponding to a contact formation region of the peripheral circuit region.

Further, a method for fabricating a non-volatile memory device in accordance with an embodiment of the present invention includes: forming a cell gate structure (CGS) where a first inter-layer dielectric layer and a first gate electrode layer are alternately stacked over a substrate of the cell region and the peripheral circuit region; forming a first trench to isolate the first gate electrode layers in one direction by selectively etching the cell gate structure (CGS) of the cell region; forming a second trench by selectively etching the cell gate structure (CGS) corresponding to a contact formation region of the peripheral circuit region; forming a selection gate structure (SGS) comprising a second inter-layer dielectric layer and a second gate electrode layer for forming a selection transistor over a substrate structure where the first and second trenches are formed; and forming a third trench and a fourth trench to expose the first and second trenches, respectively, by selectively etching the selection gate structure (SGS).

A memory device in accordance with an embodiment of the present invention includes: a substrate comprising a cell region and a peripheral circuit region; a gate structure, disposed in each of the cell region and the peripheral circuit region, comprising an inter-layer dielectric layer and a gate electrode layer that are alternately stacked; and a trench disposed to correspond to a contact formation region of the peripheral circuit region, formed in the gate structure of the peripheral circuit region.

### BRIEF DESCRIPTION OF THE DRAWINGS

FIG. 1A is a cross-sectional view illustrating a conventional non-volatile memory device having a three-dimensional structure.

FIG. 1B illustrates dish effect of the three-dimensional non-volatile memory device shown in FIG. 1A.

FIGS. 2A to 2M are cross-sectional views illustrating a non-volatile memory device having a three-dimensional structure and a method for fabricating the three-dimensional non-volatile memory device in accordance with an embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” or “over” a second layer or “on” or “over” a substrate, it not only refers to a case where the first layer is formed directly on the second layer or the substrate but also a case where one or more layers exist between the first layer and the second layer or the substrate.

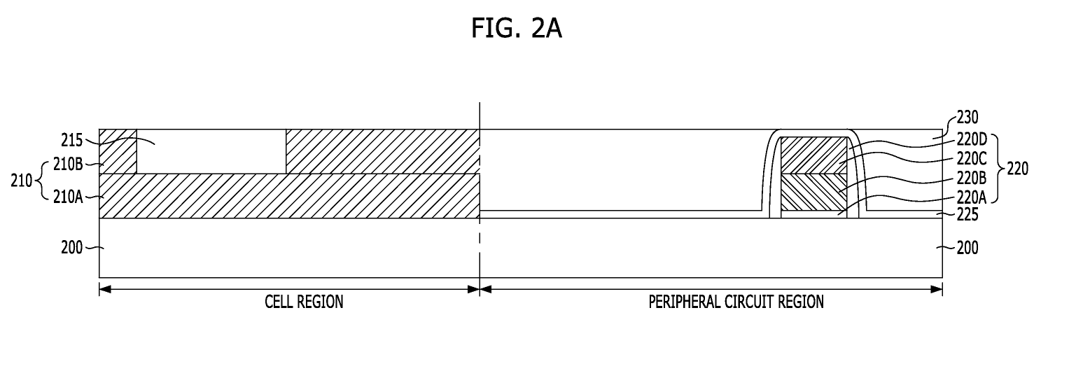

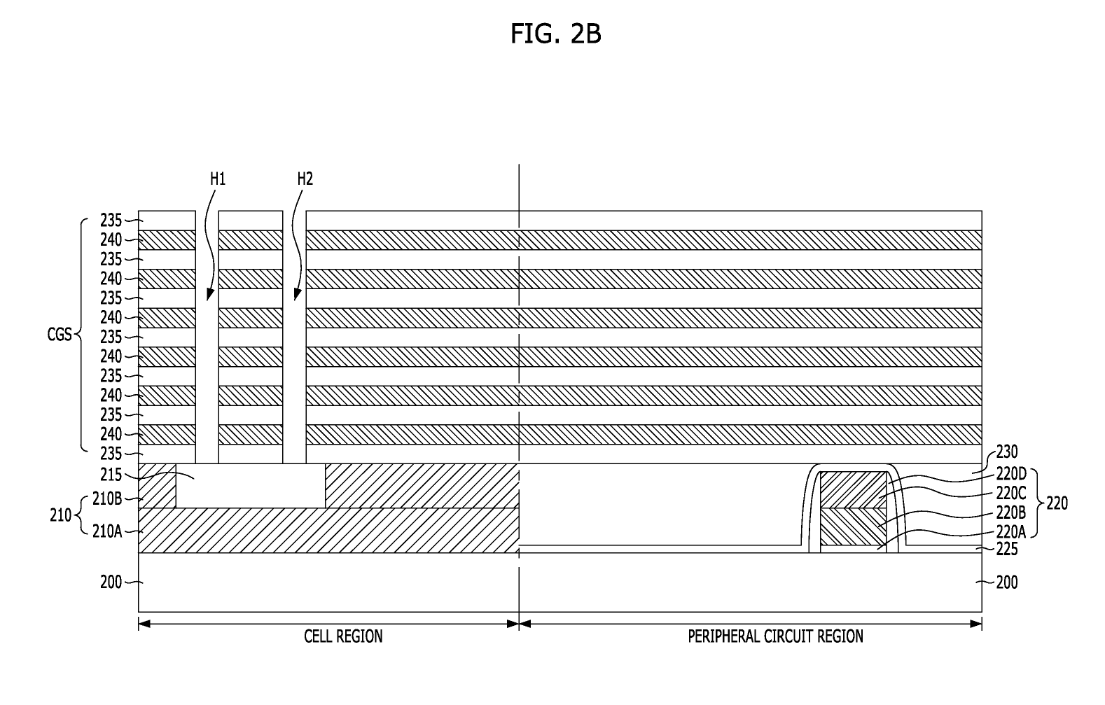

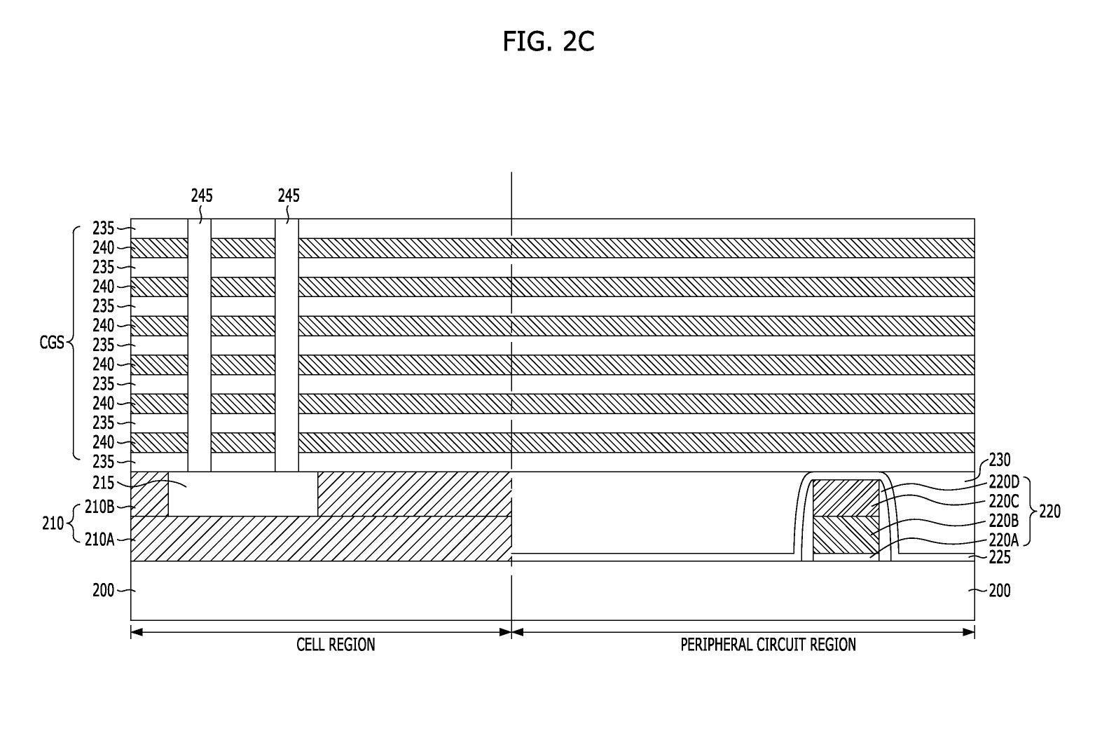

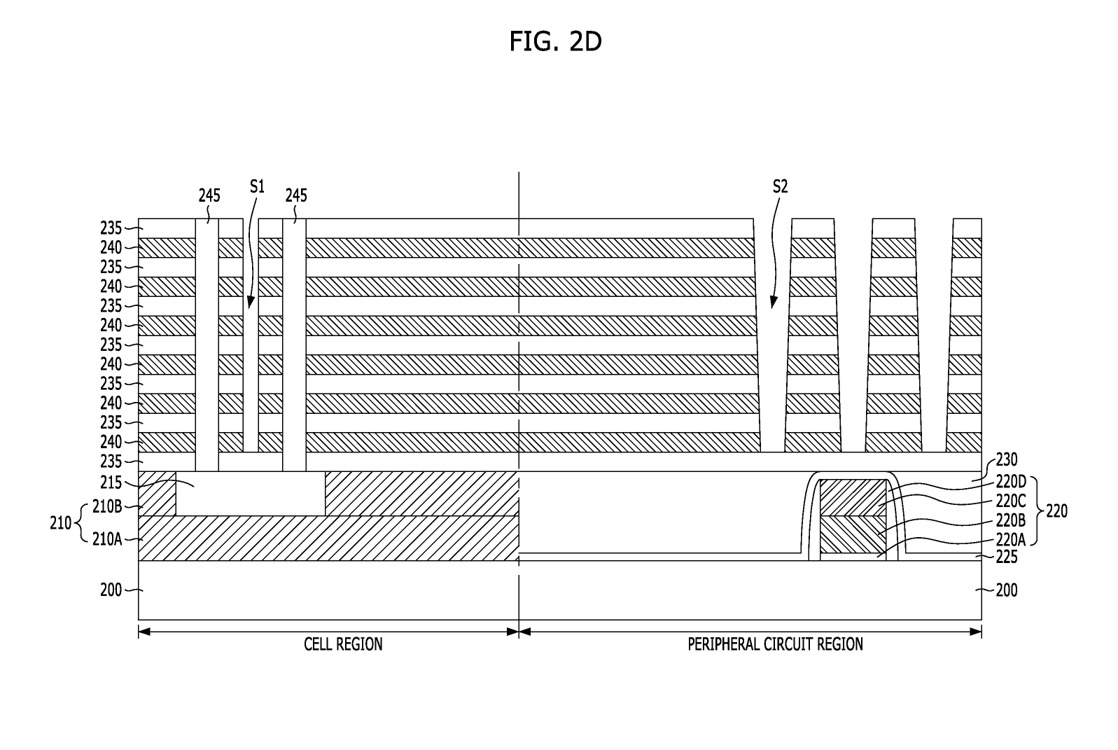

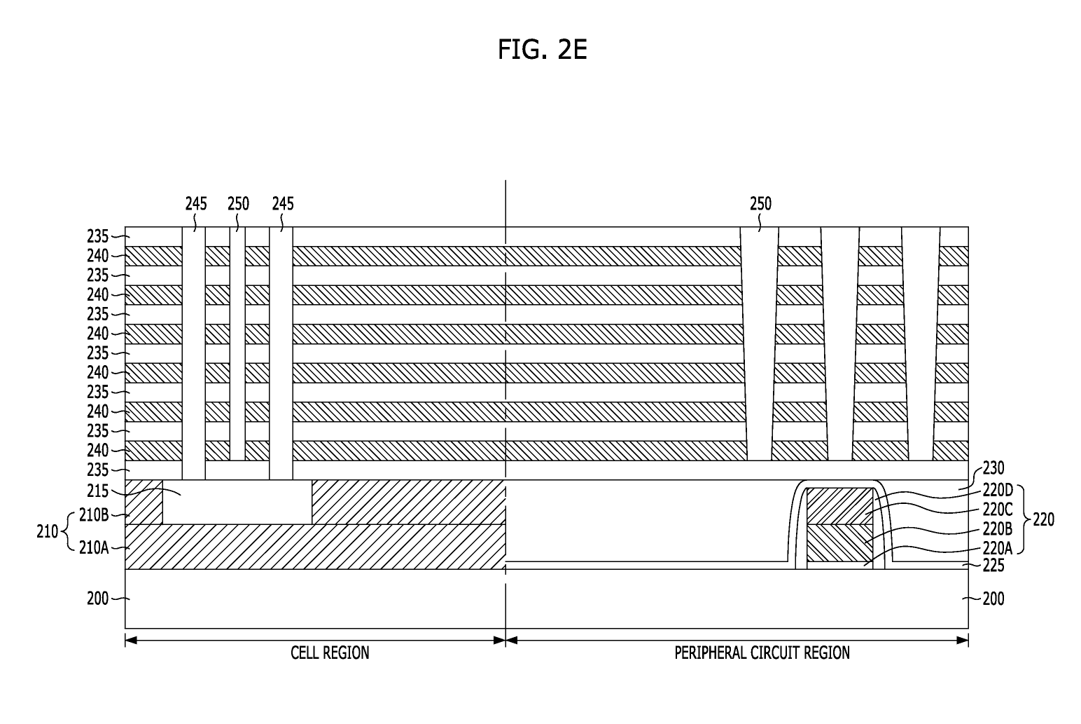

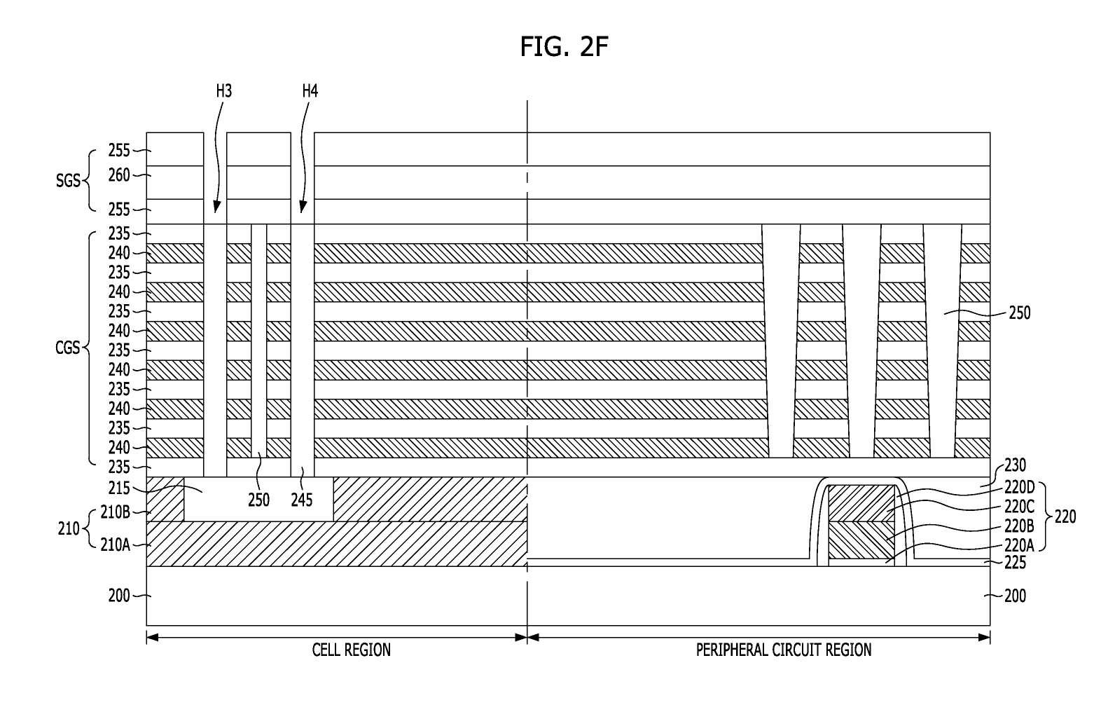

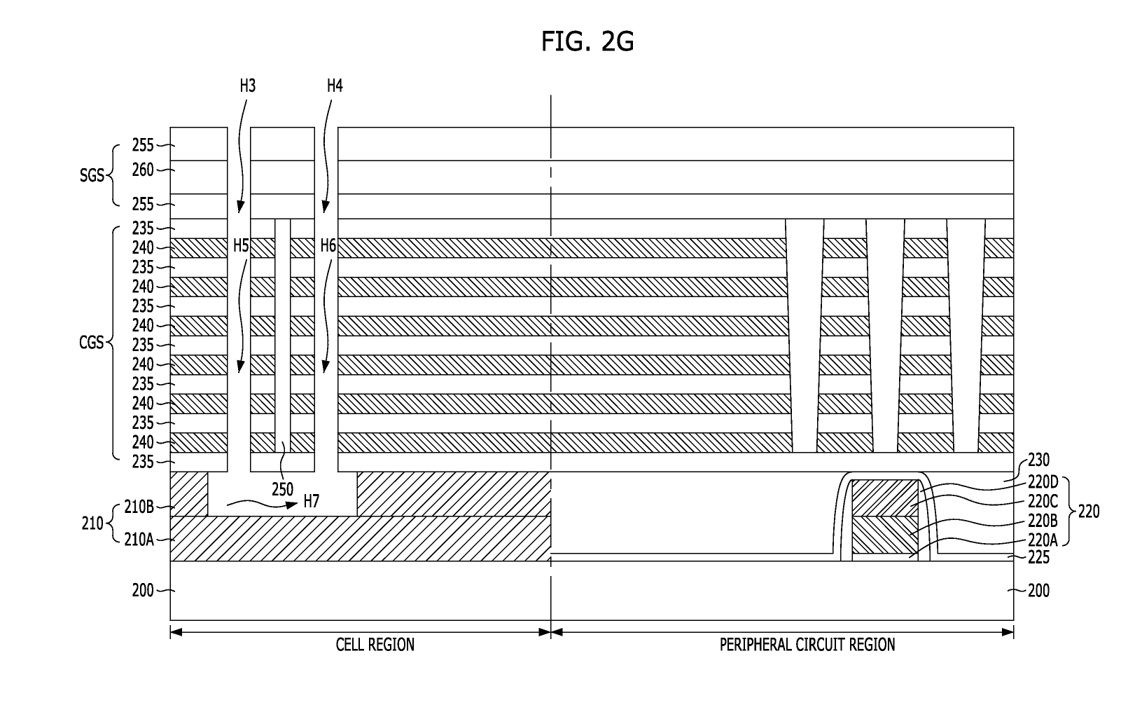

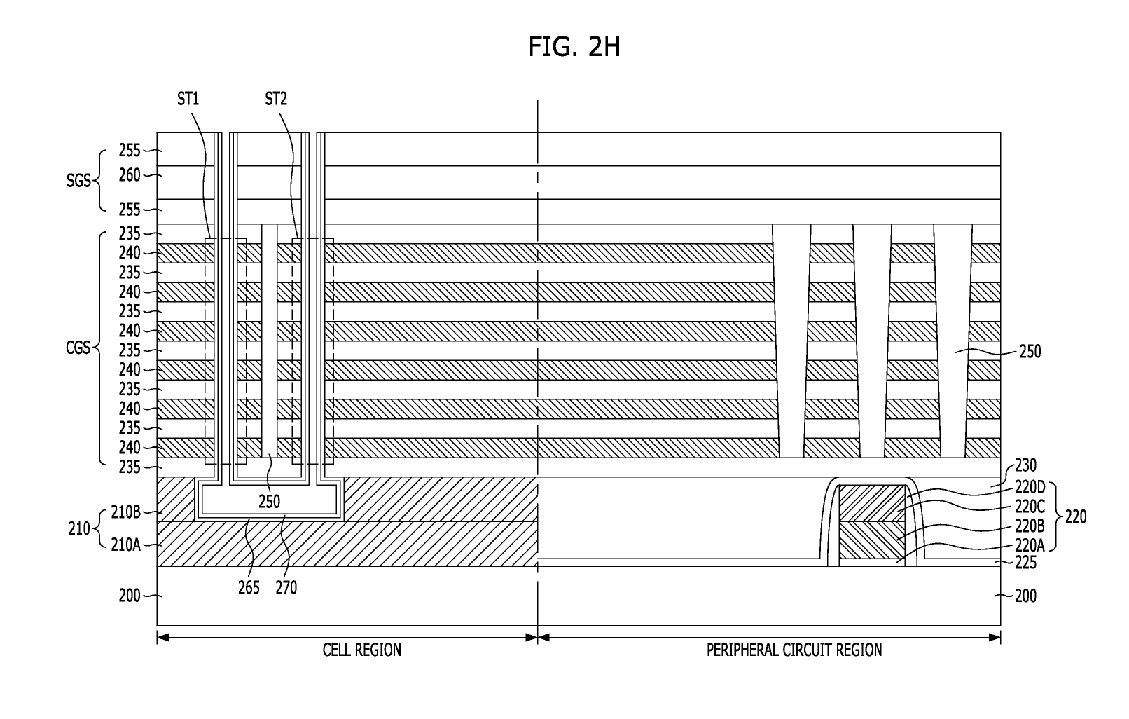

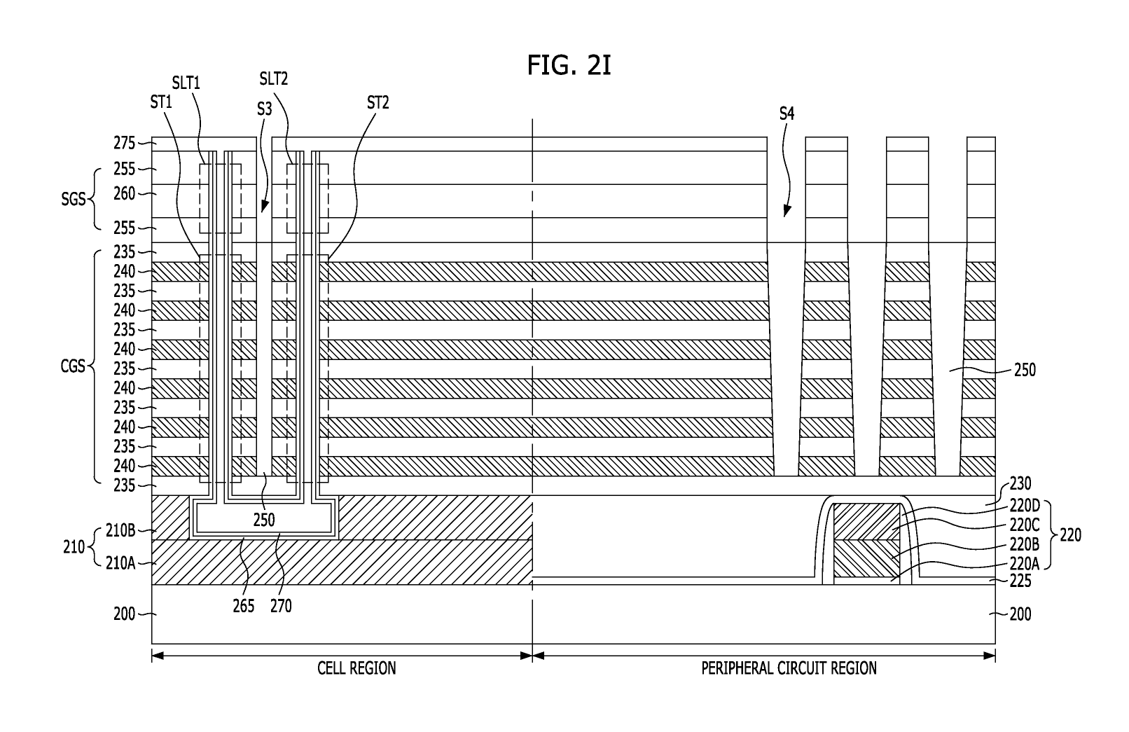

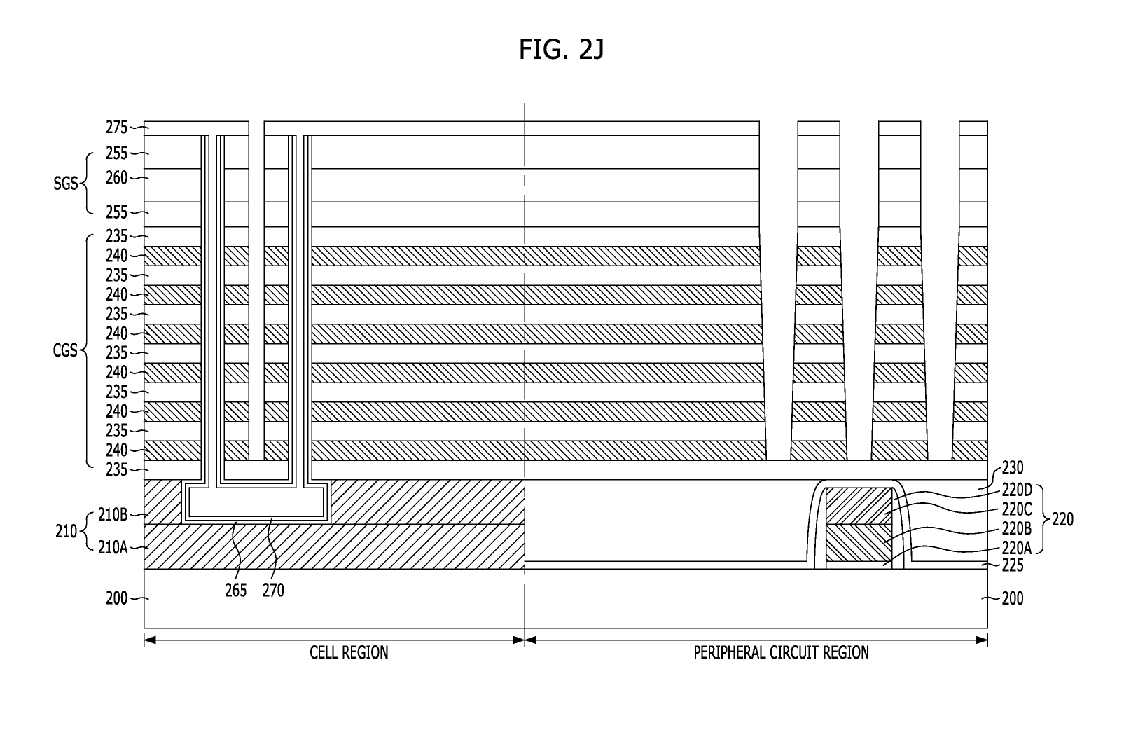

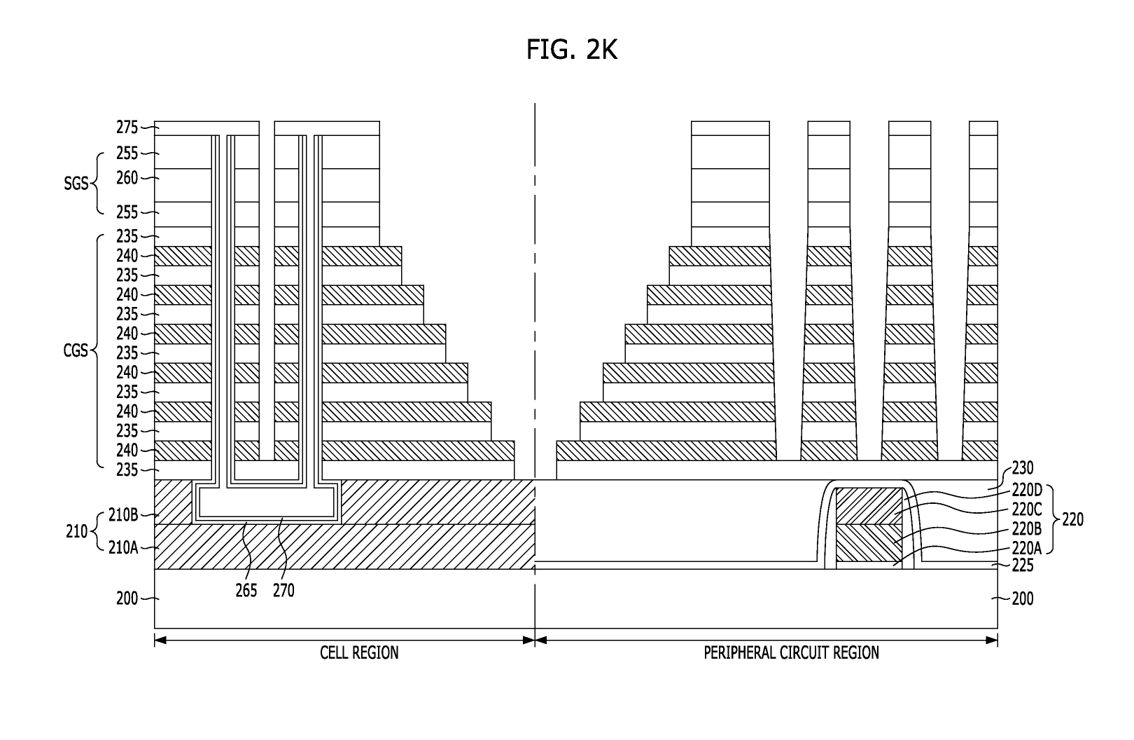

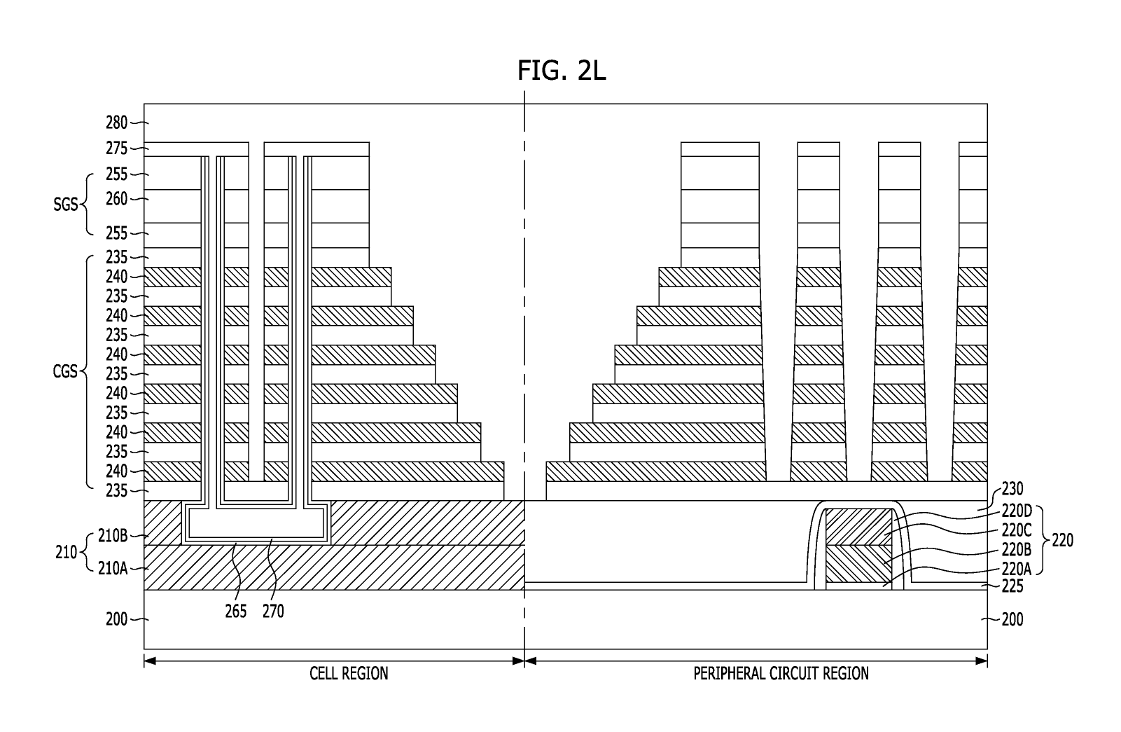

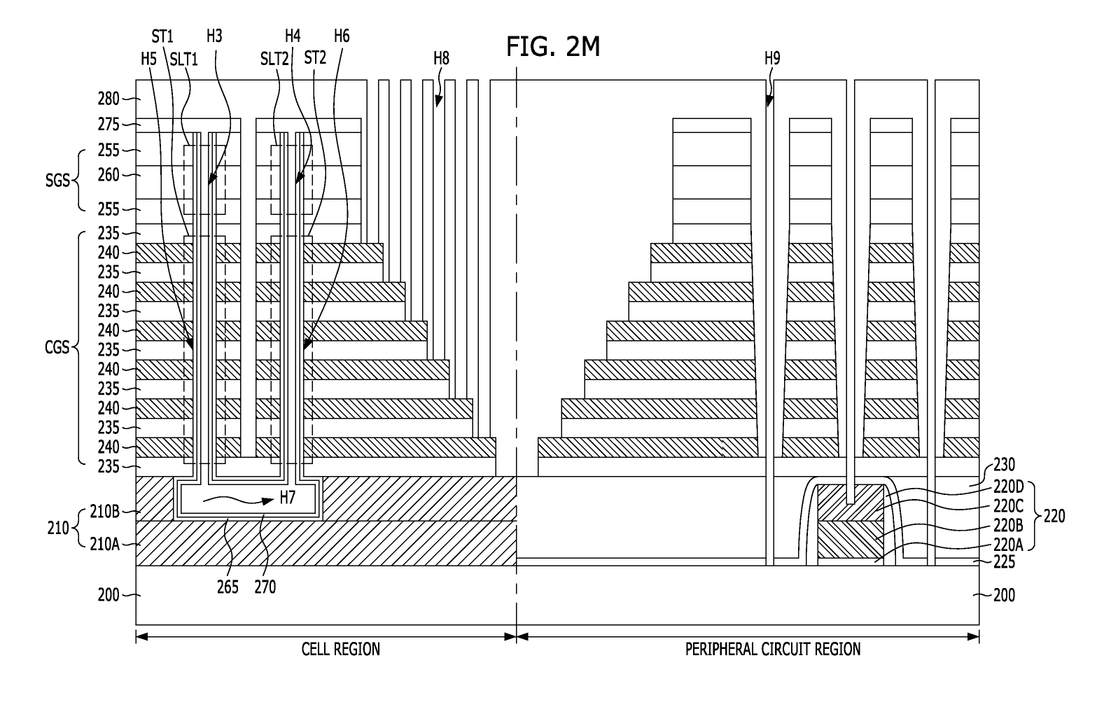

FIGS. 2A to 2M are cross-sectional views illustrating a non-volatile memory device having a three-dimensional structure and a method of fabricating a three-dimensional non-volatile memory device in accordance with an embodiment of the present invention. In particular, FIG. 2M is a cross-sectional view illustrating the non-volatile memory device having a three-dimensional structure in accordance with an embodiment of the present invention, and FIGS. 2A to 2L are cross-sectional views illustrating a method for fabricating the non-volatile memory device of FIG. 2M in accordance with an embodiment of the present invention.

The method of fabricating the non-volatile memory device having a three-dimensional structure in accordance with an embodiment of the present invention is described with reference to FIGS. 2A to 2M.

Referring to FIG. 2A, there is shown a substrate 200 having a cell region and a peripheral circuit region. The cell region is a region where a plurality of memory cells is to be formed, and the peripheral circuit region is a region where a peripheral circuit device is to be formed. The substrate 200 may be a semiconductor substrate, such as a silicon substrate, and may include an insulation layer as its upper layer.

A pipe gate electrode layer 210 filled with a first sacrificial layer 215 for forming a pipe channel is formed over the substrate 200 of the cell region.

The pipe gate electrode layer 210 may comprise a first conductive layer 210A is formed over the substrate 200 of the cell region. The first sacrificial layer 215 is formed over the first conductive layer 210A by depositing an insulation layer and patterning the insulation layer. A second conductive layer 210B may be formed over the first conductive layer 210A that may not be covered by the first sacrificial layer 215. The first conductive layer 210A and the second conductive layer 210B form the pipe gate electrode layer 210. The first conductive layer 210A and the second conductive layer 210B may be polysilicon layers doped with an impurity, and the first sacrificial layer 215 may be a nitride layer.

Also, a peripheral circuit device, for example, a peripheral circuit transistor 220 is formed over the peripheral circuit region of the substrate 200.

The peripheral circuit transistor 220 may have a stacked structure of a gate insulation layer 220A, a first gate electrode 220B, and a second gate electrode 220C over the substrate 200. The peripheral circuit transistor 220 may include a source/drain region which is not illustrated. Furthermore, the peripheral circuit transistor 220 may further include a gate spacer 220D on the sidewalls of the stacked structure of the gate insulation layer 220A, the first gate electrode 220B, and the second gate electrode 220C. A capping insulation layer 225 and an inter-layer dielectric layer 230 may be further disposed over the substrate structure including the peripheral circuit transistor 220.

Referring to FIG. 2B, a first inter-layer dielectric layer 235 and a first gate electrode layer 240 are alternately stacked to form a plurality of memory cells over the substrate structure of FIG. 2A. The stacked structure where the first inter-layer dielectric layers 235 and the first gate electrode layers 240 are alternately stacked is disposed in cell regions and peripheral regions of the substrate 200. This substantially decreases the step height between the cell regions and the peripheral regions. The stacked structure where the first inter-layer dielectric layers 235 and the first gate electrode layers 240 are alternately stacked is referred to as a cell gate structure (CGS).

The first inter-layer dielectric layer 235 isolates the multiple layers of memory cells from each other. For example, the first inter-layer dielectric layer 235 may be an oxide layer, and the first gate electrode layer 240 may be a polysilicon layer doped with an impurity. Although six layers of the first gate electrode layers 240 are shown in FIG. 2B, it should be readily understood that various numbers of layers are possible according to an embodiment of the present invention.

A first hole H1 and a second hole H2 are formed to expose the first sacrificial layer 215 by selectively etching the cell gate structure (CGS). The first hole H1 and the second hole H2 provide the space for forming a channel of the memory cells.

Referring to FIG. 2C, a second sacrificial layer 245 fills the first hole H1 and the second hole H2.

The second sacrificial layer 245 protects the first gate electrode layers 240 from being damaged when the first gate electrode layers 240 are exposed in the first hole H1 and the second hole H2 in a following process of forming the first and second trenches S1 and S2 (see FIG. 2D). The second sacrificial layer 245 may be a nitride layer. The second sacrificial layer 245 may be formed by depositing an insulation layer in the first and second holes H1, H2. A planarization process such as a Chemical Mechanical Polishing (CMP) process may be performed to expose the surface of the cell gate structure (CGS).

Referring to FIG. 2D, a first trench S1 is formed by selectively etching the cell gate structure (CGS) in the cell region between the first and second holes H1. The first trench S1 may have a shape of a slit extending in a predetermined direction, which may be in a direction perpendicular to a cross section, such as, for example, in a vertical direction.

The cell gate structure (CGS) is etched to form the first trench S1 by using the lowermost one of the first inter-layer dielectric layers 235 as an etch stop layer. Furthermore, the etch process to form the first trench S1 may be an over-etch process so that the lowermost one of the first gate electrode layers 240 is sufficiently isolated.

Although not shown in FIG. 2D, a pair of vertical strings ST1, ST2 (FIG. 2H) may be formed along cell channels (not shown) to be disposed in the first and second holes H1, H2 and isolated from each other by the first trench S1. The pair of vertical strings ST1, ST2 may be coupled with each other by a pipe transistor, which will be described later with reference to FIG. 2H, so as to form a U-shaped memory cell string.

A second trench S2 is formed by selectively etching the cell gate structure (CGS) corresponding to a region where a contact of a peripheral circuit region is to be formed. The first and second trenches S1, S2 may be formed together in a same processing step in the cell and peripheral regions, respectively. The region where a contact of a peripheral circuit region is to be formed is referred to as a contact formation region. The second trench S2 may have a shape of a slit that may extend in the same direction of the first trench S1, but it should be readily understood that other directions possible as a matter of design choice according to an embodiment of the present invention. The second trench S2 may have any shape as long as the width of the second trench S2 is not shorter than the horizontal width of the contact formation region. Also, since the second trench S2 is formed along with the first trench S1, the depths of the first and second trenches S1, S2 may be substantially same.

The contact of the peripheral circuit region may be coupled with a portion of the peripheral region, for example, a source/drain region (not shown) of the peripheral circuit transistor 220 and the second gate electrode 220C. Therefore, the second trench S2 may be formed in a region corresponding to the source/drain region (not shown) of the peripheral circuit transistor 220 and the second gate electrode 220C in the cell gate structure (CGS). This will be described later.

When the second trench S2 is formed in the contact formation region of the peripheral circuit region, the cell gate structure (CGS), and particularly, the first gate electrode layer 240, does not exist anymore in the contact formation region of the peripheral circuit region. Therefore, it is possible to form a contact in the peripheral circuit region as described below. This will be described later in detail with reference to a corresponding drawing, which is FIG. 2M. In particular, since the second trench S2 is formed along with the first trench S1 during the process for forming the first trench S1, no additional process is required.

Referring to FIG. 2E, a third sacrificial layer 250 filling the first trench S1 and the second trench S2 is formed.

The third sacrificial layer 250 may be a nitride layer. The third sacrificial layer 250 may be formed by depositing an insulation layer for forming the third sacrificial layer 250 over a substrate structure and inside the first and second trenches S1, S2. A planarization process may be performed to expose the surface of the cell gate structure (CGS).

Referring to FIG. 2F, a second inter-layer dielectric layer 255, a second gate electrode layer 260, and the second inter-layer dielectric layer 255 are sequentially formed over the substrate structure of FIG. 2E. The stacked structure of the second inter-layer dielectric layer 255, the second gate electrode layer 260, and the second inter-layer dielectric layer 255 is referred to as a selection gate structure (SGS).

The second inter-layer dielectric layer 255 may be an oxide layer, and the second gate electrode layer 260 may be a polysilicon layer doped with an impurity.

Subsequently, a third hole H3 and a fourth hole H4 are formed to expose the second sacrificial layer 245 filled in the first hole H1 and the second hole H2 by selectively etching the selection gate structure (SGS). The third hole H3 and the fourth hole H4 are formed in the regions where a channel of a selection transistor is to be formed.

Referring to FIG. 2G, the second sacrificial layer 245 exposed by the third hole H3 and the fourth hole H4 and the first sacrificial layer 215 disposed under the second sacrificial layer 245 are removed.

The process of removing the second sacrificial layer 245 and the first sacrificial layer 215 may include a wet etch process. When the second sacrificial layer 245 and/or the first sacrificial layer 215 is a nitride layer, the second sacrificial layer 245 and the first sacrificial layer 215 may be removed using an etch solution including a phosphoric acid.

As a result, cell channel holes H5 and H6 where a channel layer of the memory cells is to be formed, and a pipe channel hole H7 disposed under the cell channel holes H5 and H6 and coupling the cell channel holes H5 and H6 are formed. The cell channel holes H5 and H6 and the pipe channel hole H7 resemble a U-shape in the cross-sectional view of FIG. 2G.

Referring to FIG. 2H, a memory gate insulation layer 265 is formed on the internal walls of the U-shaped structure described above with respect to FIG. 2G, which include the third and fourth holes H3, H4, the cell channel holes H5 and H6, and the pipe channel hole H7. A channel layer 270 is then formed on the memory gate insulation layer 265.

The memory gate insulation layer 265 may be formed by sequentially depositing a charge blocking layer, a charge trapping layer, and a tunnel insulation layer. The tunnel insulation layer is a layer for charge tunneling, and the tunnel insulation layer may be an oxide layer. The charge trapping layer is a layer for trapping charges to store data, and it may be a nitride layer. The charge blocking layer is a layer for blocking the charges inside the charge trapping layer from transferring to the outside and it may be an oxide layer. The memory gate insulation layer 265 may have a triple layer structure of oxide-nitride-oxide (ONO).

The memory gate insulation layer 265 may substantially perform a function of electrically insulating the first gate electrode layer 240 and the channel layer 270 and storing data by trapping the charges between the first gate electrode layer 240 and the channel layer 270 that constitute a memory cell. The memory gate insulation layer 265 may substantially function as a gate insulation layer that electrically insulates the pipe gate electrode layer 210 and the channel layer 270 between a portion of the pipe gate electrode layer 210 and the channel layer 270 that constitute a pipe transistor. Further, the memory gate insulation layer 265 may substantially function as a gate insulation layer that electrically insulates the second gate electrode layer 260 and the channel layer 270 between a portion of the second gate electrode layer 260 and the channel layer 270 that constitute a selection transistor.

The channel layer 270 may be formed so that the channel layer 270 does not completely fill the third hole H3, the fourth hole H4, the cell channel holes H5 and H6, and the pipe channel hole H7 while being formed along the memory gate insulation layer 265. However, the invention need not be so limited. For example, in an embodiment of the invention, the channel layer 270 may fill one or more of the third hole H3, the fourth hole H4, the cell channel holes H5 and H6, and the pipe channel hole H7. The channel layer 270 may function as a channel of a pipe transistor, a channel of a memory cell, and a channel of a selection transistor.

In an embodiment of the present invention, since the memory gate insulation layer 265 and the channel layer 270 are formed on the internal walls of the U-shaped hole structure comprising the third hole H3, the fourth hole H4, the cell channel holes H5 and H6, and the pipe channel hole H7, the memory gate insulation layer 265 and the channel layer 270 can be used for the pipe transistor, the memory cell, and the selection transistor. However, a process of forming a memory gate insulation layer 265 and a channel layer 270 along the internal walls of the cell channel holes H5 and H6 and the pipe channel hole H7, and a process of forming a gate insulation layer 265 and a channel layer 270 along the internal walls of the third hole H3 and the fourth hole H4 may be performed separately.

As a result, a plurality of layers of memory cells including the first gate electrode layers 240 stacked over the substrate 200 in a vertical direction, and along the memory gate insulation layer 265 and the channel layer 270 on the internal walls of a pair of the cell channel holes H5 and H6, are formed. The multiple layers of memory cells stacked along the cell channel hole H5 on one side and the multiple layers of memory cells stacked along the cell channel hole H6 on the other side are isolated from each other by the above-described first trench S1 and form the first vertical string ST1 and second vertical string ST2. FIG. 2H shows six memory cells included in each of the first vertical string ST1 and the second vertical string ST2. However, it should be readily understood that different numbers of memory cells can be used as a matter of design choice in accordance with various embodiments of the present invention.

The first vertical string ST1 and the second vertical string ST2 are coupled to each other by a pipe transistor, which includes the memory gate insulation layer 265 and the channel layer 270 formed on the internal walls of the pipe channel hole H7, and the pipe gate electrode layer 210 surrounding the memory gate insulation layer 265 and the channel layer 270.

The first vertical string ST1, the second vertical string ST2, and the pipe transistor in between the vertical strings ST1, ST2 form a U-shaped memory cell string. In an embodiment of the present invention as shown in FIG. 2H, a U-shaped memory cell string may include 12 memory cells, but as described above the number of memory cells can vary.

Referring to FIG. 21, after a capping layer 275 for covering the substrate structure of FIG. 2H is formed, a third trench S3 for isolating the second gate electrode layer 260 between the third hole H3 and the fourth hole H4 for each of the first vertical string ST1 and the second vertical string ST2 is formed. The third trench S3 may be formed by selectively etching the selection gate structure (SGS) and the capping layer 275 between the third hole H3 and the fourth hole H4. The third trench S3 is formed to expose the third sacrificial layer 250 filling the first trench S1 and, accordingly, the third trench S3 may also have a shape of a slit extended in one direction.

As a result, a first selection transistor SLT1 and a second selection transistor may be formed. The first selection transistor SLT1 may be disposed over the first vertical string ST1 and control the first vertical string ST1, and the second selection transistor SLT2 may be disposed over the second vertical string ST2 and control the second vertical string ST2. The first selection transistor SLT1 and the second selection transistor SLT2 are isolated from each other by the third trench S3.

A fourth trench S4 may also be formed by selectively etching the selection gate structure (SGS) and the capping layer 275 of the peripheral circuit region in a same step of forming the third trench S3 in the cell region. The fourth trench S4 is formed to expose the third sacrificial layer 250 filling the second trench S2.

Referring to FIG. 2J, the third sacrificial layers 250 exposed by the third trench S3 and the fourth trench S4 are removed. This is to expose the sidewalls of the first gate electrode layer 240 and the second gate electrode layer 260 of the cell region to make it possible to perform a silicide process and, at the same time, to open a contact formation region of the peripheral circuit region.

A silicide layer (not shown) may be formed through a silicide process on the sidewalls of the first gate electrode layer 240 and the second gate electrode layer 260 that are exposed as the third sacrificial layer 250 is removed. This may decrease the resistance of the first gate electrode layer 240 and the second gate electrode layer 260.

In various embodiments of the invention, the silicide process of FIG. 2J may be omitted.

Referring to FIG. 2K, the end portions of the cell gate structure (CGS) and the selection gate structure (SGS) have a staircase shape due to using an etch process called slimming patterning when forming contacts in the cell region. The end portions of the first gate electrode layers 240 protrude in different lengths such that a lower one among the stacked structure of the first gate electrode layers 240 has its end portion protruding more than the end portion of the upper one of the first gate electrode layer 240. Furthermore, the end portion of the uppermost first gate electrode layer 240 protrudes more than the end portion of the second gate electrode layer 260.

For slimming patterning, etching is performed on the uppermost Nth layer among the N number of stacked layers using a mask having a first width. Then, the layer below the uppermost Nth layer (that is, (N-1)th layer) is etched by using a mask having a width that is adjusted by a predetermined width while maintaining the step height. As a result, two steps are formed. Subsequently, each of the (N-2)th, (N-3)th to the lowermost layer is etched in the same manner described above with the width of the mask adjusted by a predetermined width each time of etching. In this method, a structure having a staircase shape overall as shown in FIG. 2K may be formed. Alternatively, it may be possible to perform the etching process starting from the lower most layer to the uppermost Nth layer to form the overall staircase shape shown in FIG. 2K.

The slimming patterning may be performed onto the cell gate structure (CGS) and the selection gate structure (SGS) of the peripheral circuit region while the slimming patterning is performed in the cell region. As a result, as shown in FIG. 2K, the isolated end portions of the cell gate structure (CGS) and the selection gate structure (SGS) in the cell region and the isolated end portions of the cell gate structure (CGS) and the selection gate structure (SGS) of the peripheral circuit region may substantially have staircase shapes that are mirror images of each other.

The slimming patterning may isolate the cell gate structure (CGS) and selection gate structure (SGS) of the cell region from the cell gate structure (CGS) and selection gate structure (SGS) of the peripheral circuit region.

Referring to FIG. 2L, a third inter-layer dielectric layer 280 is formed to cover the substrate structure of FIG. 2K, and then a planarization process, such as CMP, is performed. The third inter-layer dielectric layer 280 may be an oxide layer.

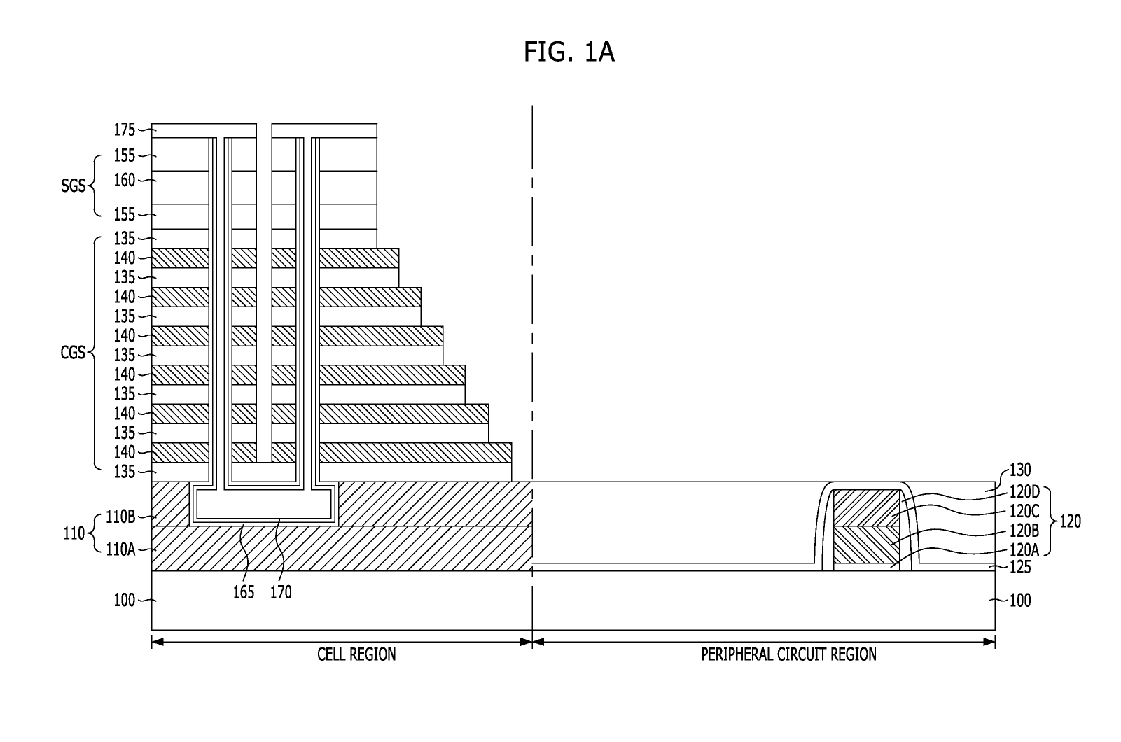

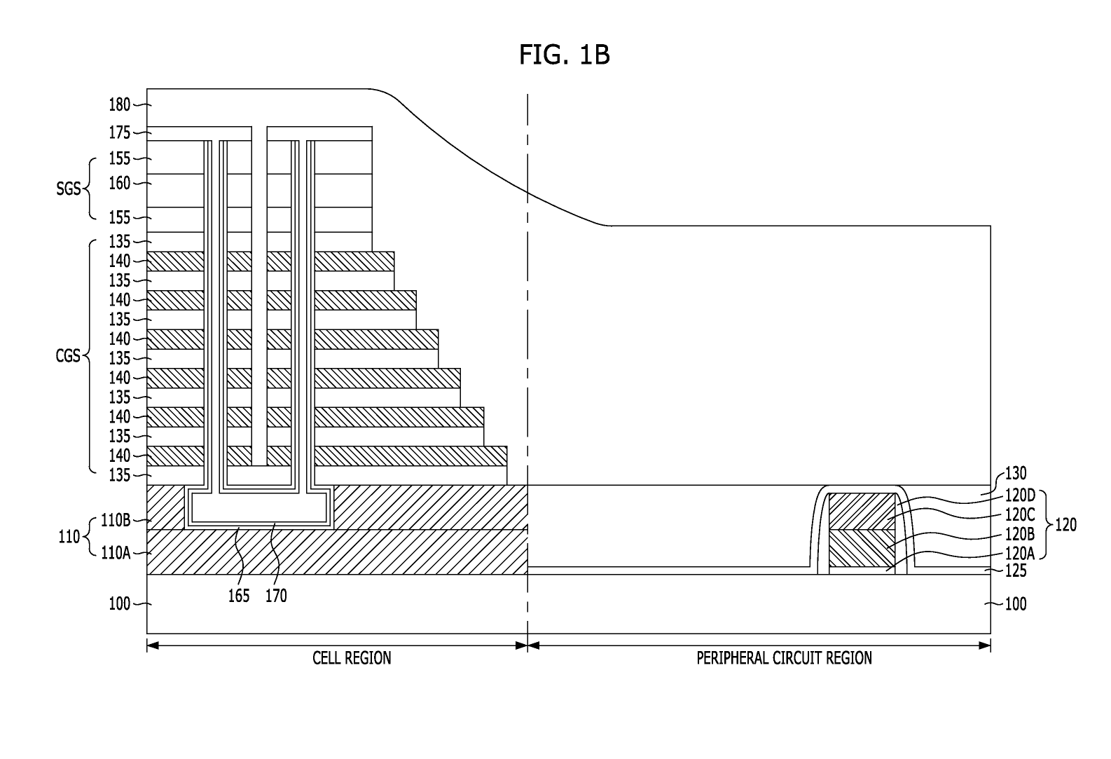

In this manner, the structures formed over both the cell region and the peripheral circuit region can have a substantially same height. Therefore, it can be seen that the third inter-layer dielectric layer 280 have generally a planar surface. The dishing effect occurring in the inter-layer dielectric layers of the peripheral circuit regions such as that shown in FIG. 1B does not occur in an embodiment of the present invention.

Referring to FIG. 2M, to form contacts in the cell region and the peripheral circuit region, contact holes H8 and H9 are formed to expose the portions required to be coupled with the predetermined lines in the cell region and the peripheral circuit region by selectively etching the third inter-layer dielectric layer 280 of the cell region and the peripheral circuit region.

For example, a plurality of first contact holes H8 each of which exposes the protruded end portion of each of the first gate electrode layers 240 may be formed in the cell region.

Also, a plurality of second contact holes H9 each of which exposes the source/drain region and the second gate electrode 220C of the peripheral circuit transistor 220 may be formed in the peripheral circuit region.

In the peripheral circuit region, a portion of the cell gate structure (CGS), particularly the first gate electrode layers 240 corresponding to the second contact holes H9, and a portion of the selection gate structure (SGS), particularly the second gate electrode layer 260 corresponding to the second contact holes H9 are removed through the aforementioned process for forming the second trench S2 and/or the fourth trench S4. The horizontal widths of the second trench S2 and/or the fourth trench S4 are greater than the horizontal width of the second contact holes H9.

Since the contacts (not shown) filling the second contact holes H9 are insulated from the first gate electrode layers 240 and the second gate electrode layer 260, it is possible to form contacts in the peripheral circuit region although there are the cell gate structure (CGS) and the selection gate structure (SGS) in the peripheral circuit region. Furthermore, according to an embodiment of the present embodiment, an etch process for forming the second contact holes H9 may be performed as described below. The third inter-layer dielectric layer 280 may be etched to form the second contact holes H9 when the third inter-layer dielectric layer 280 is etched to form the first contact holes H8 in the cell region. The thin insulation layers under the third inter-layer dielectric layer 280 of the peripheral circuit region, such as the first inter-layer dielectric layer 235 and the capping insulation layer 225, may then be removed to form the second contact holes H9.

Although not shown in FIG. 2M, the contacts may be formed by filling the first and second contact holes H8 and H9 with conductive material, such as a metal material, and predetermined lines coupled to the contacts, such as word lines and bit lines, may be formed over the third inter-layer dielectric layer 280.

The fabrication method described above in accordance with an embodiment of the present invention may alleviate step height difference between the cell region and the peripheral circuit region by forming the cell gate structure (CGS) and the selection gate structure (SGS) in the cell regions and in the peripheral circuit regions. This may also make it possible to form the contacts by removing the cell gate structure (CGS) and the selection gate structure (SGS) in advance from the contact formation region in the peripheral circuit region. Furthermore, since the process of removing the cell gate structure (CGS) and the selection gate structure (SGS) from the contact formation region of the peripheral circuit region is performed along with the process of forming trenches in the cell region, it does not require any additional process.

Referring to FIG. 2M, a non-volatile memory device in accordance with an embodiment of the present invention is described hereafter. A non-volatile memory device in accordance with an embodiment of the present invention may be fabricated according to the process shown in FIGS. 2A to 2L, but the scope and spirit of the present invention is not so limited and the non-volatile memory device in accordance with an embodiment of the present invention may be fabricated through other processes.

Referring to FIG. 2M, the pipe gate electrode layer 210 for forming a pipe transistor, the cell gate structure (CGS) where the first inter-layer dielectric layer 235 and the first gate electrode layer 240 are alternately stacked to form a plurality of layers of memory cells, and the selection gate structure (SGS) where the second inter-layer dielectric layer 255, the second gate electrode layer 260, and the second inter-layer dielectric layer 255 are sequentially stacked to form a selection transistor are sequentially disposed over the substrate 200 of a cell region.

Over the substrate 200 of a peripheral circuit region, a peripheral circuit device of the same level as that of the pipe gate electrode layer 210, for example, the peripheral circuit transistor 220, may be disposed. The capping insulation layer 225 and/or the inter-layer dielectric layer 230 may be disposed further over the peripheral circuit transistor 220.

In addition, the cell gate structure (CGS) and the selection gate structure (SGS) are disposed over the capping insulation layer 225 and the inter-layer dielectric layer 230 in the peripheral circuit region. The cell gate structure (CGS) and the selection gate structure (SGS) of the peripheral circuit region are isolated from the cell gate structure (CGS) and the selection gate structure (SGS) of the cell region. The cell gate structure (CGS) and the selection gate structure (SGS) disposed over the substrate 200 of the peripheral circuit region are not for forming memory cells and selection transistors. Rather, they are dummies disposed to alleviate step height difference between the cell region and the peripheral circuit region.

As described above, the pipe transistor, the multiple layers of memory cells, and the selection transistors are sequentially disposed over the substrate 200 of the cell region. Therefore, the following structure are further disposed in the pipe gate electrode layer 210, the cell gate structure (CGS), and the selection gate structure (SGS) of the cell region.

A pair of cell channel holes H5 and H6 penetrating the cell gate structure (CGS) is disposed in the inside of the cell gate structure (CGS), and the pipe channel hole H7 coupling the cell channel holes H5 and H6 is disposed in the inside of the pipe gate electrode layer 210. In the inside of the selection gate structure (SGS), the third hole H3 and the fourth hole H4 coupled with the pair of cell channel holes H5 and H6 are disposed penetrating the selection gate structure (SGS).

The memory gate insulation layer 265 and the channel layer 270 are disposed on the internal walls of the third and fourth holes H3 and H4, the cell channel holes H5 and H6, and the pipe channel hole H7. However, the scope and spirit of the present invention are not so limited. According to various embodiments of the present invention, the memory gate insulation layer 265 and the channel layer 270 are disposed on the internal walls of the cell channel holes H5 and H6 and the pipe channel hole H7, and on the internal walls of the third hole H3 and the fourth hole H4, a gate insulation layer different from the memory gate insulation layer 265, and a channel-forming layer different from the channel layer 270 may be disposed.

The multiple first gate electrode layers 240 between the cell channel holes H5 and H6 are isolated from each other by the first trench S1, which penetrates the cell gate structure (CGS) except the lowermost first inter-layer dielectric layer 235. Also, the second gate electrode layer 260 between the third hole H3 and the fourth hole H4 is isolated from each other by the third trench S3 which penetrates the selection gate structure (SGS).

Consequently, the pipe transistor, the first and second vertical strings ST1 and ST2, and the first and second selection transistors SLT1 and SLT2 are disposed over the substrate 200 of the cell region. The pipe transistor may include the pipe gate electrode layer 210, and the memory gate insulation layer 265 and the channel layer 270 on the internal walls of the pipe channel hole H7. Herein, the first and second vertical strings ST1 and ST2 are the multiple layers of memory cells, which are formed of the memory gate insulation layer 265 and the channel layer 270 formed on the internal walls of the cell channel holes H5 and H6, and the first gate electrode layers 240 vertically stacked along the memory gate insulation layer 265 and the channel layer 270, and isolated for each of the cell channel holes H5 and H6. The first and second selection transistors SLT1 and SLT2 include the memory gate insulation layer 265 and the channel layer 270 formed on the internal walls of the third hole H3 and the fourth hole H4 and the second gate electrode layer 260 and are isolated for each of the third hole H3 and the fourth hole H4.

Since the cell gate structure (CGS) and the selection gate structure (SGS) disposed in the substrate 200 of the peripheral circuit region are dummies, a channel layer or a memory gate insulation layer is not disposed in the peripheral circuit region. However, if there are any cell gate structure (CGS) and selection gate structure (SGS) in a contact formation region of the peripheral circuit region, the first gate electrode layer 240 of the cell gate structure (CGS) or the second gate electrode layer 260 of the selection gate structure (SGS) may be shorted from the contact.

Therefore, the cell gate structure (CGS) and the selection gate structure (SGS) are removed from the contact formation region of the peripheral circuit region, and the space from which the cell gate structure (CGS) and the selection gate structure (SGS) are removed is filled with an insulation layer such as, for example, the third inter-layer dielectric layer 280. Herein, the horizontal width of the space from which the cell gate structure (CGS) and the selection gate structure (SGS) are removed may be greater than the horizontal width of the contact formation region of the peripheral circuit region.

The isolated end portions of the cell gate structure (CGS) and the selection gate structure (SGS) in the cell region and the isolated end portions of the cell gate structure (CGS) and the selection gate structure (SGS) of the peripheral circuit region may substantially have, for example, staircase shapes mirroring each other. In other words, any first gate electrode layer 240 has its end portion protruded more than that of the first gate electrode layer 240 above it, and the uppermost first gate electrode layer 240 has its end portion protruded more than the second gate electrode layer 260.

The third inter-layer dielectric layer 280 is disposed over the cell gate structures (CGS) and the selection gate structures (SGS) of the cell region and the peripheral circuit region. The first contact holes H8 penetrating the third inter-layer dielectric layer 280 of the cell region may expose the end portions of each of the first gate electrode layers 240. The second contact holes H9 penetrating the third inter-layer dielectric layer 280 of the peripheral circuit region further penetrate the insulation layers under the third inter-layer dielectric layer 280 to thereby expose each of the source/drain region and the second gate electrode 220C of the peripheral circuit transistor 220.

According to an embodiment of the present invention, a non-volatile memory device may have a decreased step height between a cell region and a peripheral circuit region, have contacts formed in peripheral circuit regions, and be fabricated although a plurality of memory cells are vertically stacked in cell regions, and a method may be described for fabricating the same.

While the present invention has been described with respect to specific embodiments, it will be apparent to those skilled in the art that various changes and modifications may be made in other embodiments without departing from the spirit and scope of the invention as defined in the following claims.

For example, the technology of the present invention is not only applied to the above-described embodiment but also it may be applied to all structures where a conductive layer and an insulation layers are alternately stacked in order to facilitate a process for forming contacts and lines over the contacts while decreasing the step height between cell regions and peripheral circuit regions.

What is claimed is:

1. A method of fabricating a memory device, comprising:
forming a gate structure where an inter-layer dielectric layer and a gate electrode layer are alternately stacked in a cell region and a peripheral circuit region;
forming a first trench to isolate the gate electrode layers in one direction by selectively etching the gate structure of the cell region; and
forming a second trench by selectively etching the gate structure corresponding to a contact formation region of the peripheral circuit region.

2. The method of claim 1, wherein a horizontal width of the second trench is greater than a horizontal width of a contact to be formed in the contact formation region of the peripheral circuit region.

3. The method of claim 1, further comprising:
filling the second trench with an insulation layer; and
forming a contact hole by selectively etching the insulation layer in the second trench of the contact formation region of the peripheral circuit region.

4. The method of claim 1, wherein the first and second trenches are formed in a same step.

5. The method of claim 1, wherein the gate structure formed in the cell region and the gate structure formed in the peripheral circuit region are isolated from each other.

6. The method of claim 1, wherein the gate structure formed in the cell region comprises a first gate electrode layer whose end portion protrudes more than an end portion of a second gate electrode layer above the first gate electrode layer.

7. The method of claim 6, comprising:
filling the second trench with an insulation layer as part of the process of covering the gate structure in the cell region with the insulation layer;
forming first contact holes, each exposing a corresponding one of the protruded end portion of each of the first and second gate electrode layers by selectively etching the insulation layer covering gate structure in the cell region; and
forming a second contact hole by selectively etching the insulation layer in the second trench of the contact formation region of the peripheral circuit region.

8. A method of fabricating a memory device, comprising:
forming a cell gate structure where a first inter-layer dielectric layer and a first gate electrode layer are alternately stacked over a substrate of a cell region and a peripheral circuit region;
forming a first trench to isolate the first gate electrode layers in one direction by selectively etching the cell gate structure of the cell region;
forming a second trench by selectively etching the cell gate structure corresponding to a contact formation region of the peripheral circuit region;
forming a selection gate structure comprising a second inter-layer dielectric layer and a second gate electrode layer for forming a selection transistor over a substrate structure where the first and second trenches are formed; and
forming a third trench and a fourth trench to expose the first and second trenches, respectively, by selectively etching the selection gate structure.

9. The method of claim 8, wherein horizontal widths of the second and fourth trenches are greater than a horizontal width of a contact to be formed in the contact formation region of the peripheral circuit region.

10. The method of claim 8, further comprising:
filling the second trench and the fourth trench with an insulation layer by forming the insulation layer covering the cell gate structure and the selection gate structure; and
forming a contact hole by selectively etching the insulation layer in the second and fourth trenches of the contact formation region of the peripheral circuit region.

11. The method of claim 8, wherein the cell gate structure and the selection gate structure of the cell region and the cell gate structure and the selection gate structure of the peripheral circuit region are isolated from each other.

12. The method of claim 8, wherein a first of the first gate electrode layers of the cell gate structure in the cell region has an end portion that protrudes more than an end portion of a second of the first gate electrode layers above the first of the first gate electrode layers.

13. The method of claim 12, comprising:
filling the second trench and the fourth trench with an insulation layer by forming the insulation layer covering the cell gate structure and the selection gate structure;
forming a first contact hole exposing protruded end portion of each of the first gate electrode layers by selectively etching the insulation layer of the cell region; and
forming a second contact hole by selectively etching the insulation layer in the trench in the contact formation region of the peripheral circuit region.

14. The method of claim 8, further comprising:
forming a pair of cell channel holes that penetrate the cell gate structure of the cell region and are isolated from each other by the first trench; and
forming a pair of selection transistor channel holes that penetrate the selection gate structure to expose the pair of cell channel holes and are isolated from each other by the third trench,
wherein the substrate of the cell region comprises a pipe gate electrode layer having a pipe channel hole and the pair of cell channel holes are coupled with each other by the pipe channel hole.

15. The method of claim 14, further comprising:
forming a memory gate insulation layer and a channel layer on internal walls of the pipe channel hole, the pair of cell channel holes, and the pair of selection transistor channel holes.

16. A memory device, comprising:
a substrate comprising a cell region and a peripheral circuit region;
a gate structure, disposed in each of the cell region and the peripheral circuit region, comprising an inter-layer dielectric layer and a gate electrode layer that are alternately stacked; and
a trench, disposed to correspond to a contact formation region of the peripheral circuit region, formed in the gate structure of the peripheral circuit region.

17. The memory device of claim 16, wherein a horizontal width of the trench is greater than a horizontal width of a contact formed in the contact formation region of the peripheral circuit region.

18. The memory device of claim 16, further comprising:
a first trench disposed inside the gate structure of the cell region,
wherein the first trench isolates the gate electrode layers in one direction, and
the first trench and the trench have substantially the same depth.

19. The device of claim 16, further comprising:
an insulation layer configured to cover the gate structure while filling the trench; and
a contact hole configured to penetrate the insulation layer of the contact formation region of the peripheral circuit region.

20. The memory device of claim 16, wherein the gate structure of the cell region and the gate structure of the peripheral circuit region are isolated from each other.

21. The memory device of claim 16, wherein a first gate electrode layer in the cell region has an end portion that protrudes more than an end portion of a second gate electrode layer above the first gate electrode layer.

22. The memory device of claim 21, comprising:
an insulation layer configured to cover the gate structures in the cell region and the peripheral circuit region while filling the trench;
a first contact hole configured to expose protruded end portion of each of the gate electrode layers by penetrating the insulation layer of the cell region; and
a second contact hole configured to penetrate the insulation layer of the contact formation region of the peripheral circuit region.

23. The memory device of claim 16, wherein the gate structure comprises:
a cell gate structure where a first inter-layer dielectric layer and a first gate electrode layer are alternately stacked to form the memory cells; and
a selection gate structure disposed over the cell gate structure and comprising a second inter-layer dielectric layer and a second gate electrode layer to form a selection transistor.

24. The memory device of claim 23, further comprising:
a pair of cell channel holes that penetrate the cell gate structure of the cell region and are isolated from each other by the first trench; and
a pair of selection transistor channel holes that penetrate the selection gate structure to expose the pair of cell channel holes and are isolated from each other by the first trench,
wherein the substrate of the cell region comprises a pipe gate electrode layer having a pipe channel hole, and the pair of cell channel holes are coupled with each other by the pipe channel hole.

25. The memory device of claim 22, further comprising:
a memory gate insulation layer and a channel layer disposed on internal walls of the pipe channel hole, the pair of cell channel holes, and the pair of selection transistor channel holes.
